(19) United States
(12) Patent Application Publication
(10) Pub. No.: US 2011/0056430 A1
(43) Pub. Date: Mar. 10, 2011

(54) EQUIPMENT FOR GROWING SAPPHIRE SINGLE CRYSTAL

(76) Inventors: Keigo HOSHIKAWA, Nagano-shi (JP); Chihiro Miyagawa, Nagano-shi (JP); Taichi Nakamura, Nagano-shi (JP)

(21) Appl. No.: 12/873,617

(22) Filed: Sep. 1, 2010

(30) Foreign Application Priority Data
Sep. 8, 2009 (JP) 2009-206949

(51) Int. Cl. C30B 15/14

(52) U.S. Cl. 117/217

(57) ABSTRACT

The equipment for growing a sapphire single crystal is capable of easily improving shape accuracy and positioning accuracy of a thermal shield which influence temperature distribution in a growth furnace. The thermal shield is provided in the growth furnace and encloses the cylindrical heater so as to form a hot zone. The thermal shield is constituted by a plurality of cylindrical sections, which are vertically stacked and whose radial positions are defined by a positioning mechanism. The cylindrical sections are composed of carbon felt.

### CROSS-REFERENCE TO RELATED APPLICATION

This application is based upon and claims the benefit of priority of the prior Japanese Patent Application No. P2009-206949, filed on Sep. 8, 2009, and the entire contents of which are incorporated herein by reference.

### FIELD

The present invention relates to an equipment for growing a sapphire single crystal by performing the unidirectional solidification method.

### BACKGROUND

Sapphire has been used for a number of things. These days, it is important to use sapphire substrates for producing LEDs. In this field, an LED substrate is produced mainly by epitaxially-growing a buffer layer and a gallium nitride film on a sapphire substrate.

Therefore, a method for growing a sapphire single crystal which is capable of efficiently and stably growing sapphire has been required.

Most of sapphire substrates used for producing LEDs are substrates of c-plane (0001). Conventionally, in the industrial field, sapphire single crystals are grown by the edge-defined film-fed growth (EFG) method, the Kyropoulos (KP) method, the Czochralski (CZ) method, etc. In case of growing a single crystal whose diameter is three inches or more, various crystal defects will generate therein, so a single crystal grown in a-axis has been alternately used. To grow c-axis sapphire crystal boule by processing the a-axis sapphire crystal, the a-axis sapphire crystal must be hollowed from a side. Therefore, the above described conventional technology has following disadvantages: processing the crystal is difficult; large disused parts must be left; and material yield must be lowered.

The vertical Bridgeman method (vertical gradient freeze method) has been known as a method for growing an oxide single crystal. In the vertical Bridgeman method, a thin-walled crucible is used so as to easily take out a grown crystal therefrom. However, a sapphire single crystal is grown from high temperature melt, so a material of the thin-walled crucible, which has high strength and high chemical resistance under high temperature, has been required. Japanese Laid-open Patent Publication No. P2007-119297A discloses a material having high strength and high chemical resistance under high temperature.

Japanese Laid-open Patent Publication No. P7-277869A discloses a conventional method, in which the vertical Bridgeman method is performed and a thermal shield composed of carbon felt is provided in a crystal growth furnace in which a crucible is set.

In case of growing a sapphire single crystal having no crystal defects, by the vertical Bridgeman method, in a single crystal growth equipment, it is required to highly prevent variation of temperature distribution (including temperature gradient) in a growth furnace for growing the crystal. Namely, the temperature distribution is much influenced by shape accuracy and positioning accuracy of a thermal shield. If the accuracies are lower, the temperature distribution including the temperature gradient will be significantly varied and reproducibility of the crystal will be lower.

Conventionally, ceramics, e.g., Alumina Ceramics (Al₂O₃), and Zirconia Ceramics (ZrO₂) are used as a material of the thermal shield. However, in case that heat shock is applied to the thermal shield composed of such material, cracks will be formed in the thermal shield. Further, the thermal shield is gradually decomposed under high temperature, oxygen is generated therefrom, and carbons sublimes, so the ceramic and zirconia are unsuitable materials for the thermal shield of a sapphire single crystal growth equipment.

On the other hand, the carbon felt disclosed in Japanese Laid-open Patent Publication No. P7-277869A is a soft material, so the problem of forming cracks under high temperature can be solved. However, load bearing is low and the shape is gradually changed by applying load, so it is difficult to treat large carbon felt. As described above, reproducibility of the crystal will be lower by varying the temperature distribution in the growth furnace, so deformation of the thermal shield must be prevented and positioning accuracy thereof must be improved so as to prevent variation of the temperature distribution in the growth furnace and improve the reproducibility of the crystal.

### SUMMARY

Accordingly, it is an object in one aspect of the invention to provide an equipment for growing a sapphire single crystal, which are capable of easily improving shape accuracy and positioning accuracy of a thermal shield which influence temperature distribution in a growth furnace.

To achieve the object, the present invention has following structures.

Namely, the equipment of the present invention grows a sapphire single crystal by performing the steps of: putting a seed crystal and a raw material in a crucible; setting the crucible in a cylindrical heater located in a growth furnace; and heating the crucible, by the cylindrical heater, so as to melt the raw material and a part of the seed crystal,

a thermal shield is provided in the growth furnace, the thermal shield encloses the cylindrical heater so as to form a hot zone,

the thermal shield is constituted by a plurality of cylindrical sections, which are vertically stacked and whose radial positions are defined by positioning means, and

the cylindrical sections are composed of carbon felt.

In the present invention, shape accuracy and positioning accuracy of the thermal shield which influence temperature distribution in the growth furnace can be easily improved.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Embodiments of the present invention will now be described by way of examples and with reference to the accompanying drawings, in which:

FIG. 1 is a front sectional view of an embodiment of the equipment for growing a sapphire single crystal relating to the present invention;

FIG. 2 is a schematic view of an example of a thermal shield (a large diameter cylindrical section) used in the equipment shown in FIG. 1;

FIG. 3 is a schematic view of an example of a thermal shield (a small diameter cylindrical section) used in the equipment shown in FIG. 1;

FIG. 4 is a schematic view of an example of an framing section (a ring-shaped part) used in the equipment shown in FIG. 1;

FIG. 5 is a schematic view of an example of an framing section (a cylindrical part) used in the equipment shown in FIG. 1;

FIGS. 6A-6C are front sectional views of examples of the thermal shields used in the equipment shown in FIG. 1; and

FIGS. 7A-7F are explanation views showing the steps of crystallizing sapphire and annealing the crystal performed in the equipment shown in FIG. 1.

### DETAILED DESCRIPTION OF THE EMBODIMENTS

Preferred embodiments of the present invention will now be described in detail with reference to the accompanying drawings.

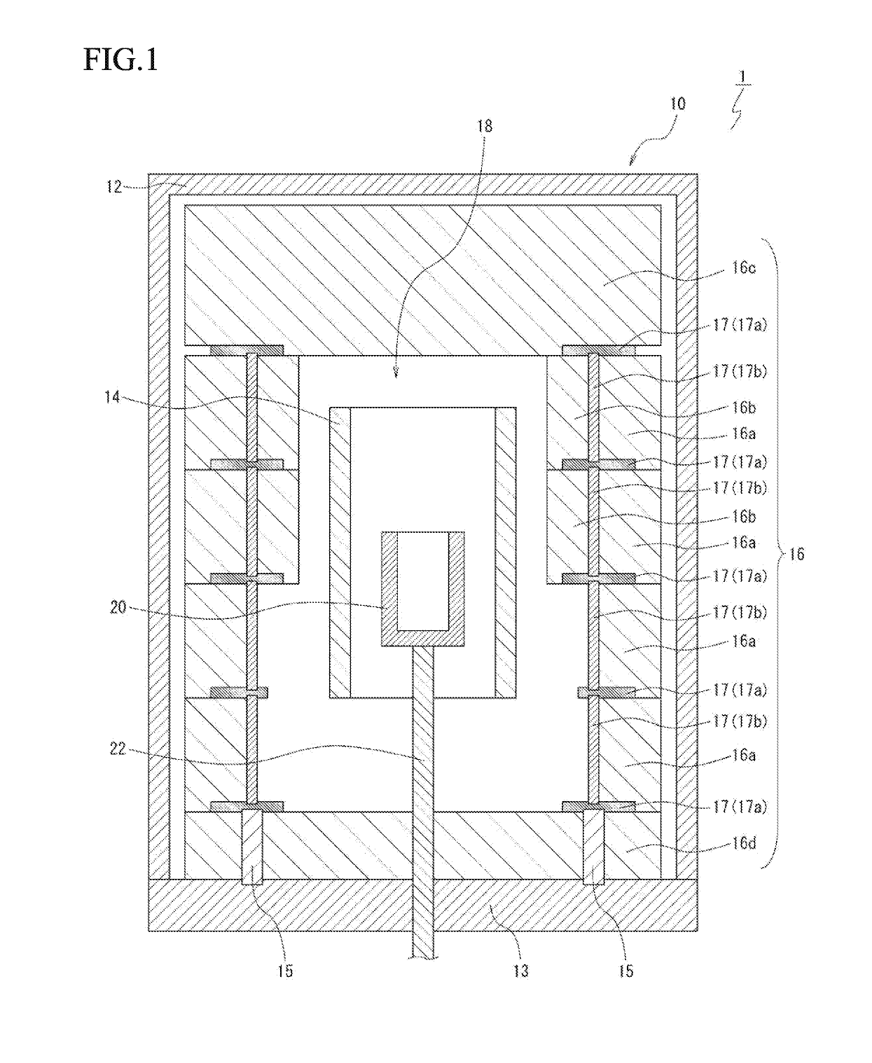

FIG. 1 is a front sectional view of an equipment 1 for growing a sapphire single crystal. In the present embodiment, the equipment 1 has a growth furnace 10, in which a sapphire single crystal is grown by performing the known vertical Bridgeman method. The structure of the growth furnace 10 will be briefly explained. An inner space of the growth furnace 10 is tightly enclosed by cylindrical jackets 12, through which cooling water is circulated, and a base 13. At least one cylindrical heater 14, which is vertically arranged, is provided in the inner space of the growth furnace 10. In the present embodiment, one cylindrical heater 14 is used. Note that, a size of the growth furnace 10 is based on a size of a sapphire single crystal to be grown. In the present embodiment, a diameter of the growth furnace 10 is about 0.5 m, and a height thereof is about 1 m.

In the present embodiment, the cylindrical heater 14 is a carbon heater. A control section (not shown) controls electric power distribution to the cylindrical heater 14 so as to adjust temperature of the cylindrical heater 14. Material properties of the cylindrical heater 14, etc. are shown in TABLE.

A thermal shield 16 is provided around the cylindrical heater 14. The thermal shield 16 forms a hot zone 18. Details of the thermal shield 16 will hereinafter be described.

By controlling the electric power distribution to the cylindrical heater 14, vertical temperature gradient can be produced in the hot zone.

TABLE

| | Cylindrical | Framing | Thermal |
|---|---|---|---|
| | Heater | Section | shield |
| Material | Isotropic | Carbon | Carbon Felt |
| | Graphite | Material for | |
| | (CIP) | Extrusion | |
| Density [g/cm³] | 1.8 | 1.73 | 0.16 |
| Specific | | | |
| Resistance | 12.5 | 7.5 | — |
| [μΩm] | | | |
| Thermal | | | |
| Expansion | 4.8 | 4.4 | 4.48 |
| Coefficient | | | |
| [10⁻⁶/K] | | | |
| Thermal | | | |
| Conductivity | 128 | 180 | 0.14 |
| [W/(mK)] | | | |
| Bending | | | |
| Strength [MPa] | 54 | 24-30 | 0.68-0.99 |

A symbol 20 stands for a crucible. An upper end of a crucible shaft 22 is connected to a bottom part of the crucible 20. By moving the crucible shaft 22 upward and downward, the crucible 20 can be vertically moved in the cylindrical heater 14. The crucible 20 can be rotated by rotation of the crucible shaft 22.

The crucible shaft 22 is vertically moved by a ball screw (not shown). Therefore, a vertical moving speed of the crucible can be precisely controlled while moving upward or downward.

The growth furnace 10 has two opening parts (not shown), and an inert gas, preferably an argon gas, is supplied to and discharged from the opening parts. While growing a crystal, the growth furnace 10 is filled with an inert gas. Note that, thermometers (not shown) are provided at a plurality of places in the growth furnace 10.

Preferably, the crucible 20 is composed of a material having a specific linear expansion coefficient which is capable of preventing mutual stress, which is caused by a difference between a linear expansion coefficient of the crucible and a linear expansion coefficient of the sapphire single crystal to be grown in a direction perpendicular to a growth axis of the sapphire single crystal, from generating in the crucible 20 and the grown sapphire single crystal, or which is capable of preventing deformation of the crucible 20 caused by the mutual stress without generating a crystal defect or defects caused by the mutual stress in the grown sapphire single crystal.

Preferably, the crucible 20 is composed of a material whose linear expansion coefficient between the melting temperature of sapphire (2050° C.) and the room temperature is smaller than that of the sapphire single crystal to be grown, in the direction perpendicular to the growth axis, while cooling the crystal from the melting temperature of sapphire (2050° C.) to the room temperature.

More preferably, the crucible 20 is composed of a material whose linear expansion coefficient, between the melting temperature of sapphire and each of optional temperatures equal to or higher than the room temperature, is always smaller than that of the sapphire single crystal to be grown, in the direction perpendicular to the growth axis, while cooling the crystal from the melting temperature of sapphire (2050° C.) to the room temperature.

The material of the crucible 20 may be, for example, tungsten, molybdenum, or an alloy of tungsten and molybdenum.

Especially, the linear expansion coefficient of tungsten is smaller than that of sapphire at each temperature. In each of the crucibles 20 composed of the above described materials, a rate of shrinkage of the crucible 20 is smaller than that of sapphire while performing a crystallizing step, an annealing step and a cooling step, so that an inner wall face of the crucible 20 is separated from an outer face of a grown sapphire single crystal, no stress is applied to the grown sapphire single crystal and forming cracks in the crystal can be prevented.

Next, the insulating material 16, which is one of unique features of the present embodiment, will be explained.

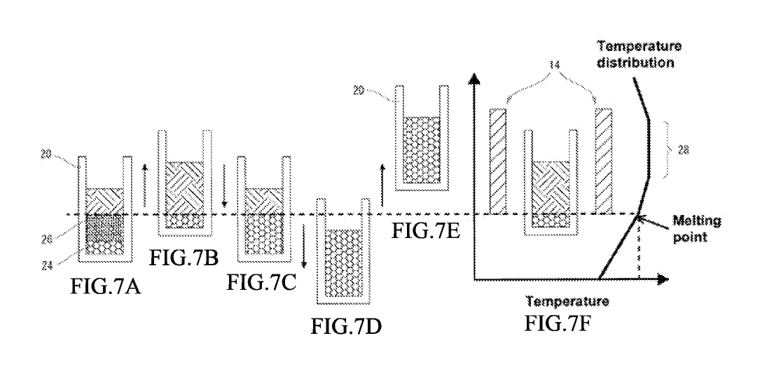

The thermal shield 16 has a tube-shaped part, which encloses at least an outer circumferential face of the cylindrical heater 14. Further, as shown in FIG. 1, a radial thickness of an upper part of the tube-shaped part, which corresponds to the upper part of the growth furnace 10 where the temperature is high according to desired temperature gradient (see FIG. 7E), is thicker than that of a lower part thereof; a radial thickness of the lower part of the tube-shaped part, which corresponds to the lower part of the growth furnace 10 where the temperature is low according to the temperature gradient, is thinner than that of the upper part thereof.

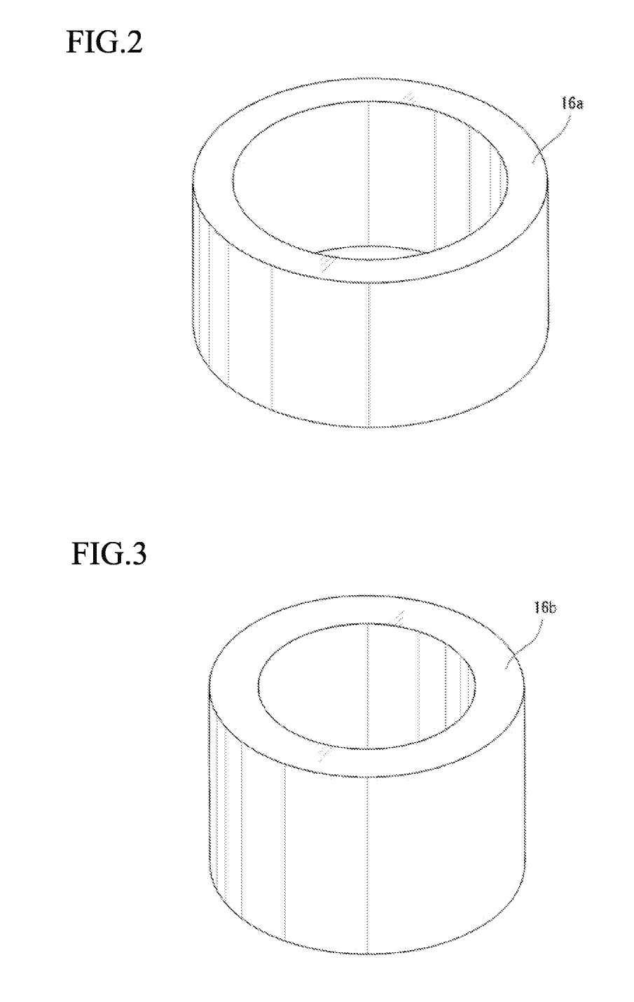

In the present embodiment, the upper-thicker part of the tube-shaped part of the thermal shield 16 is constituted by a cylindrical section 16a having a large diameter (see FIG. 2) and a cylindrical section 16b having a small diameter (see FIG. 3) which are radially and coaxially stacked. On the other hand, the lower-thinner part of the tube-shaped part of the thermal shield 16 is constituted by the large diameter cylindrical section 16a or a small diameter cylindrical section 16b. In the present embodiment, the lower-thinner part is constituted by the large diameter cylindrical section 16a only (see FIG. 1). For example, the cylindrical sections 16a and 16b are composed of carbon felt whose properties are shown in the above TABLE.

A thermal shield 16c, which is formed into a circular plate shape or a columnar shape, is provided on the uppermost cylindrical sections 16a and 16b. In the present embodiment, the thermal shield 16c is provided on an uppermost ring-shaped part 17, but the thermal shield 16c may be provided on the uppermost cylindrical sections 16a and 16b directly. Note that, the thermal shield 16c may be constituted by layering a plurality of circular plate-shaped members.

Further, a thermal shield 16d is provided to a bottom part. For example, the thermal shield 16d is formed into a circular plate shape or a columnar shape and has a through-hole through which the crucible shaft 22 pierces.

In the present embodiment, the cylindrical sections 16a and 16b and the thermal shields 16c and 16d are composed of the same material, e.g., carbon felt. By employing the carbon felt as the material of such members, the problem of forming cracks under high temperature, which is the problem of the conventional insulating materials, e.g., ceramics, zirconia, can be solved.

As described above, the thermal shield 16 is provided around the cylindrical heater 14, so that a hot zone 18 enclosed by the thermal shield 16 is formed.

In the equipment 1, a sapphire single crystal is grown by the unidirectional solidification method comprising the steps of: putting a seed crystal 24 and a raw material 26 in the crucible 20; setting the crucible 20 in the cylindrical heater 14 located in the growth furnace 10; heating the crucible 20 so as to melt the raw material 26 and a part of the seed crystal 24; and producing the temperature gradient in the cylindrical heater 14, in which temperature of the upper part is higher than the lower part, so as to sequentially crystallize the melt of the raw material 26 and the seed crystal 24. The optimum temperature gradient for growing the sapphire single crystal (see FIG. 7E) can be produced in the growth furnace 10. Further, the temperature gradient can be easily controlled by adjusting the radial thickness of the thermal shield 16 (the cylindrical sections 16a and 16b) in the upper and lower parts of the growth furnace 10.

In case of a small-sized growth furnace 10, the thermal shield 16 may be a non-divided thermal shield, or the thermal shield 16 may be divided into two or three. On the other hand, in case of a large-sized growth furnace 10, the thermal shield 16 must be large in size, so it is difficult to manufacture the non-divided thermal shield. Even if a large non-divided thermal shield 16 is manufactured, it is difficult to handle the large one. Further, the thermal shield 16 must be heavy, so the lowermost part of the thermal shield 16 must be deformed, by own weight, when the thermal shield 16 is installed or while operating the equipment 1. Temperature distribution (including the temperature gradient) in the growth furnace 10 will be varied by the deformation, and crystal defects will be formed in the single crystal grown therein.

To solve the problem, in the present embodiment, the tube-shaped part of the thermal shield 16, which encloses the outer circumferential face of the cylindrical heater 14, is constituted by a plurality of the cylindrical sections 16a and 16b which are vertically stacked (see FIG. 1). Further, a framing section 17 vertically supports all or a part of the cylindrical sections 16a and 16b and defines their vertical and radial positions.

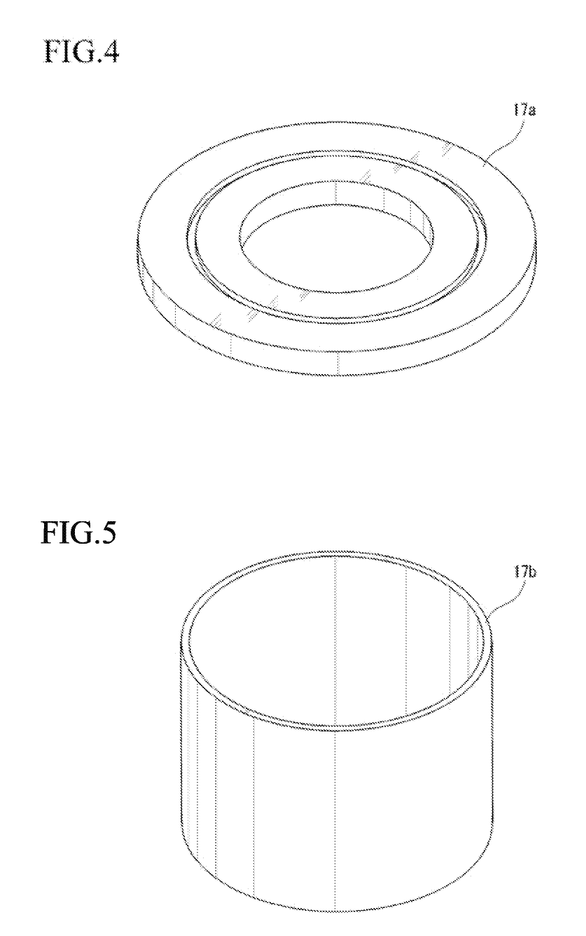

In the present embodiment, as shown in FIG. 1, the framing section 17 includes: ring-shaped parts 17a (see FIG. 4), on each of which the cylindrical section 16a, 16b or 16c is mounted; and cylindrical parts 17b, each of which vertically supports a total weight of the ring-shaped part 17a and the cylindrical sections 16a, 16b and/or 16c. In the present embodiment, the framing section 17 (the ring-shaped parts 17a) is fixed to the base 13 of the growth furnace 10 by pillars 15. For example, the ring-shaped parts 17a and the cylindrical parts 17b are formed by molding a carbon material. Properties of the carbon material are shown in the above TABLE. The pillars 15 are composed of quartz.

Note that, the ring-shaped part 17a shown in FIG. 4 is an example, so an inner diameter, an outer diameter, a groove shape, etc. may be optionally designed according to location, etc.

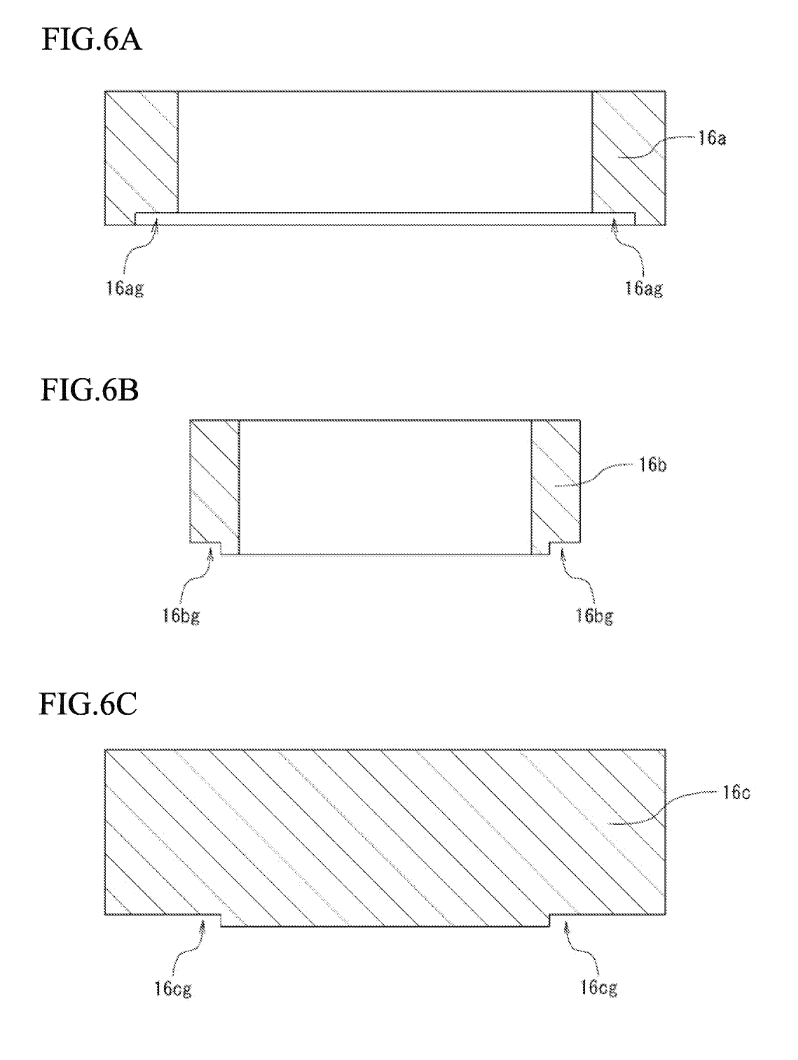

Further, in the present embodiment, grooves are formed in bottom faces of the cylindrical sections 16a and 16b and the thermal shield 16c, and the ring-shaped parts 17a are tightly fitted in the grooves respectively. Namely, the cylindrical section 16a has the groove 16ag, the cylindrical section 16b has the groove 16bg and the thermal shield 16c has the groove 16cg (see FIG. 6A which is a front sectional view of the cylindrical section 16a, FIG. 6B which is a front sectional view of the cylindrical section 16b, and FIG. 6C which is a front sectional view of the thermal shield 16c).

By fitting the ring-shaped parts 17a in the grooves 16ag, 16bg and 16cg respectively, the radial positions of the cylindrical sections 16a and 16b and the thermal shield 16c can be correctly defined and set.

By forming the grooves 16ag, 16bg and 16cg, the radial positions of the cylindrical sections 16a and 16b can be correctly defined and set. Further, by making an outer diameter of the cylindrical part 17b and an inner diameter of the large diameter cylindrical section 16a equal and making an inner diameter of the cylindrical part 17b and an outer diameter of the small diameter cylindrical section 16b equal, the radial positions of the cylindrical sections 16a and 16b can be correctly defined and set without forming the grooves 16ag, 16bg and 16cg.

By dividing the thermal shield into a plurality of the members 16a-16d and using the framing section 17, the above described problems caused by growing in size and increasing weight of the thermal shield 16 can be solved.

The cylindrical sections 16a and 16b, which are vertically stacked, are composed of carbon felt, so they will be deformed and their positions will be displaced. Especially, in case of growing a sapphire single crystal, controlling temperature gradient in the growth furnace 10 is very important factor. If the cylindrical sections 16a and 16b are slightly deformed or their positions are slightly displaced, temperature distribution, including the temperature gradient, in the growth furnace 10 will be significantly varied, reproducibility of the crystal will be lower and crystal defects will be formed in the grown single crystal.

However, by employing the structure of the present embodiment, the framing section 17 is capable of supporting the total weight of the stacked thermal shield 16, which is vertically applied. Therefore, the deformation of the thermal shield 16 (the members 16a-16d) can be prevented.

Further, the radial positions of the cylindrical sections 16a and 16b can be correctly defined and set, so that displacement thereof can be prevented.

By the above described structure of the present embodiment, variation of the temperature distribution, including the temperature gradient, in the growth furnace 10, can be prevented and forming crystal defects in the grown single crystal can be prevented, so that a high quality single crystal can be grown in the equipment of the present embodiment.

Note that, in case of using the small-sized growth furnace 10, the radial positions of the cylindrical sections 16a and 16b and the thermal shield 16c, which are vertically stacked, can be defined and set without using the framing section 17. For example, projections (not shown), which correspond to the grooves 16ag, 16bg and 16cg respectively, are grown on the upper faces of the cylindrical sections 16a and 16b and fitted to the grooves, so that the radial positions of the cylindrical sections 16a and 16b and the thermal shield 16c can be defined and set.

Next, the crystallizing step and the annealing step will be explained with reference to FIGS. 7A-7F.

In FIG. 7A, a sapphire seed crystal 24 and a raw material 26 are put in the crucible 20.

Temperature of a hot zone of the growth furnace 10 enclosed by the cylindrical heater 14 is controlled. Namely, as shown in FIG. 7F, temperature of an upper part of the hot zone is higher than the melting temperature of sapphire; temperature of a lower part thereof is lower than the melting temperature of sapphire.

The crucible 20, in which the sapphire seed crystal 24 and the raw material 26 have been accommodated, are moved from the lower part of the hot zone to the upper part thereof. When the raw material 26 and an upper part of the sapphire seed crystal 24 are melted, the upward movement of the crucible 20 is stopped (see FIG. 7B). Next, the crucible 20 is moved downward at a predetermined slow speed (see FIG. 7C). With these actions, the melt of the raw material 26 and the sapphire seed crystal 24 is gradually crystallized and deposits along a crystal plane of the remaining sapphire seed crystal 24 (see FIGS. 7C and 7D).

The sapphire seed crystal 24 is set in the crucible 20, and c-plane of the sapphire seed crystal 24 is horizontalized. The melt is grown along the c-plane, i.e., in the direction of c-axis.

Since crucible 20 is composed of the above described material, e.g., tungsten, the inner wall face of the crucible 20 is separated from the outer face of the grown sapphire single crystal while performing the crystallizing step, the annealing step and the cooling step. Therefore, no external stress is applied to the grown sapphire crystal and forming cracks therein can be prevented. Further, no stress is applied to the inner wall face of the crucible 20 and the grown crystal, so that the grown crystal can be easily taken out from the crucible 20 and the crucible 20 can be repeatedly used without being deformed.

In the present embodiment, the inner space of the cylindrical heater 14 is cooled, in the same growth furnace 10, until reaching prescribed temperature, e.g., 1800° C., by reducing heating power of the cylindrical heater 14 after crystallizing the melt, and the crucible 20 is upwardly moved until reaching a soak zone 28 (see FIG. 7F) of the cylindrical heater 14, which is a mid part thereof and in which temperature gradient is lower than other parts (see FIG. 7E). The crucible 20 is placed in the soak zone 28 for a predetermined time period, e.g., one hour, so as to anneal the sapphire single crystal in the crucible 20.

By annealing the sapphire single crystal on the crucible 20 in the same growth furnace 10, the annealing step can be efficiently performed, thermal stress in the grown crystal can be eliminated. Therefore, the high quality sapphire single crystal, which has few crystal defects, can be grown. Since the grown crystal on the crucible 20 can be crystallized and annealed in the same growth furnace 10, desired crystals can be efficiently grown and energy consumption can be lowered. Note that, the above described annealing treatment effectively removes residual stress of the grown crystal. In case that the grown crystal is less stressed, the annealing treatment may be omitted.

In the above described embodiment, the vertical Bridgeman method (unidirectional solidification method) is performed. Further, single sapphire crystals may be crystallized and annealed by other unidirectional solidification methods, e.g., vertical gradient freezing (VGF) method. In the vertical gradient freeze method too, a crucible is upwardly moved, in a cylindrical heater, until reaching a soak zone to perform the annealing step.

In the above described embodiment, the growth axis of the crystal is the c-axis. Further, a-axis or a direction perpendicular to r-plane may be the growth axis.

As described above, in the equipment of the present invention, the heat-insulation structure of the growth furnace is realized by the thermal shields composed of carbon felt, instead of ceramics and zirconia which have been used in conventional equipments.

By employing the thermal shield constituted by a plurality of the sections and members, the problems caused by growing in size and increasing weight of the thermal shield can be solved. The optimum temperature gradient can be produced in the growth furnace by varying the radial thickness of the thermal shield in the vertical direction. Further, deformation and displacement of the thermal shield can be prevented, so that shape accuracy and positioning accuracy of the thermal shield, which influence the temperature distribution in the growth furnace, can be secured.

Therefore, forming crystal defects in the sapphire single crystal can be prevented, so that a high quality sapphire single crystal can be grown.

The equipment of the present invention is suitable for growing a sapphire single crystal, but it may be used for growing other single crystals.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention has been described in detail, it should be understood that the various changes, substitutions, and alternations could be made hereto without departing from the spirit and scope of the invention.

What is claimed is:

1. An equipment for growing a sapphire single crystal, in which the sapphire single crystal is grown by the steps of: putting a seed crystal and a raw material in a crucible; setting the crucible in a cylindrical heater located in a growth furnace; and heating the crucible, by the cylindrical heater, so as to melt the raw material and a part of the seed crystal,
wherein a thermal shield is provided in the growth furnace, the thermal shield encloses the cylindrical heater so as to form a hot zone,
the thermal shield is constituted by a plurality of cylindrical sections, which are vertically stacked and whose radial positions are defined by positioning means, and
the cylindrical sections are composed of carbon felt.

2. The equipment according to claim 1,
wherein the thermal shield further has a framing section for vertically supporting weights of all or a part of the cylindrical sections.

3. The equipment according to claim 1,
wherein temperature gradient, in which temperature of an upper part is higher than that of a lower part, is grown in the growth furnace so as to perform the unidirectional solidification method for sequentially crystallizing a melt of the raw material and the seed crystal,
the thermal shield has a tube-shaped part, which encloses at least an outer circumferential face of the cylindrical heater,
a radial thickness of an upper part of the tube-shaped part, which corresponds to the upper part of the growth furnace where the temperature is high according to the temperature gradient, is thicker than that of a lower part thereof, and
a radial thickness of the lower part of the tube-shaped part, which corresponds to the lower part of the growth furnace where the temperature is low according to the temperature gradient, is thinner than that of the upper part thereof.

4. The equipment according to claim 2,
wherein temperature gradient, in which temperature of an upper part is higher than that of a lower part, is grown in the growth furnace so as to perform the unidirectional solidification method for sequentially crystallizing a melt of the raw material and the seed crystal,
the thermal shield has a tube-shaped part, which encloses at least an outer circumferential face of the cylindrical heater,
a radial thickness of an upper part of the tube-shaped part, which corresponds to the upper part of the growth furnace where the temperature is high according to the temperature gradient, is thicker than that of a lower part thereof, and
a radial thickness of the lower part of the tube-shaped part, which corresponds to the lower part of the growth furnace where the temperature is low according to the temperature gradient, is thinner than that of the upper part thereof.

5. The equipment according to claim 2,
wherein the framing section includes: a ring-shaped part, on which the cylindrical sections are mounted; and a cylindrical part, which supports a total weight of the ring-shaped part and the cylindrical sections, and
the ring-shaped part and the cylindrical part are formed by molding a carbon material.

6. The equipment according to claim 2,
wherein the thermal shield includes a circular plate member being provided on the uppermost cylindrical section directly or with the framing section, and
the circular plate member is composed of carbon felt.

7. The equipment according to claim 4,
wherein the upper-thicker part of the tube-shaped part of the thermal shield, which corresponds to the upper part of the growth furnace, is constituted by a small diameter cylindrical section and a large diameter cylindrical section which are radially stacked, and
the lower-thinner part of the tube-shaped part of the thermal shield, which corresponds to the lower part of the growth furnace, is constituted by a small diameter cylindrical section or a large diameter cylindrical section.
